(19) United States
(12) Patent Application Publication
(10) Pub. No.: US 2026/0032997 A1
(43) Pub. Date: Jan. 29, 2026

(54) INTEGRATED CIRCUIT SEMICONDUCTOR DEVICE

(71) Applicant: Samsung Electronics Co., Ltd., Suwon-si (KR)

(72) Inventors: Donghyun Seo, Suwon-si (KR); Wooseok Park, Suwon-si (KR)

(21) Appl. No.: 19/238,634

(22) Filed: Jun. 16, 2025

(30) Foreign Application Priority Data
Jul. 25, 2024 (KR) 10-2024-0098965

(51) Int. Cl. H10D 84/83; H10D 84/01

(52) U.S. Cl. CPC H10D 84/833; H10D 84/0151

(57) ABSTRACT

An integrated circuit semiconductor device includes a plurality of fin-type active regions protruding from a substrate and spaced apart from each other, nano sheet stacking structures on the fin-type active regions, placeholders within the fin-type active regions, source and drain regions on the placeholders, a dielectric wall structure between a pair of the fin-type active regions and separating the pair of fin-type active regions, the nano sheet stacking structures thereon, the placeholders therein, and the source and drain regions thereon. The field regions are within trenches in the substrate, which separate the fin-type active regions. The field regions each include a multi-insulating layer. A plurality of gate structures are provided on the nano sheet stacking structures.

### CROSS-REFERENCE TO RELATED APPLICATIONS

This application is based on and claims priority under 35 U.S.C. § 119 to Korean Patent Application No. 10-2024-0098965, filed on Jul. 25, 2024, in the Korean Intellectual Property Office, the disclosure of which is incorporated by reference herein in its entirety.

### TECHNICAL FIELD

The inventive concept relates to an integrated circuit semiconductor device, and more particularly, to an integrated circuit semiconductor device including a nano sheet transistor.

### BACKGROUND

As the integration of integrated circuit semiconductor devices has increased, the size of the devices has been reduced and the scaling of the devices may approach limits. Accordingly, it may be desirable to develop further methods, such as through structural changes in devices, to improve the performance and enhance the reliability of the devices.

### SUMMARY

The inventive concept provides an integrated circuit semiconductor device including a nano sheet transistor and having improved device performance and reliability.

According to an aspect of the inventive concept, an integrated circuit semiconductor device includes a plurality of fin-type active regions protruding from a substrate, extending in a first direction on the substrate, and spaced apart from each other in a second direction intersecting the first direction; nano sheet stacking structures on the fin-type active regions; a dielectric wall structure extending in the first direction, wherein the dielectric wall structure is between a pair of the fin-type active regions and is between the nano sheet stacking structures thereon in the second direction; field regions within trenches in the substrate that separate the fin-type active regions, the field regions comprising a multi-insulating layer; and a plurality of gate structures extending in the second direction on the nano sheet stacking structures and spaced apart from each other in the first direction.

According to another aspect of the inventive concept, an integrated circuit semiconductor device includes a plurality of fin-type active regions protruding from a substrate and spaced apart from each other; nano sheet stacking structures on the fin-type active regions; placeholders within the fin-type active regions; source and drain regions on the placeholders; a dielectric wall structure separating a pair of the fin-type active regions, the dielectric wall structure extending between pair of the fin-type active regions, between the nano sheet stacking structures thereon, between the placeholders therein, and between the source and drain regions thereon; field regions within trenches in the substrate that separate the fin-type active regions, the field regions each comprising a multi-insulating layer; and a plurality of gate structures on the nano sheet stacking structures.

According to another aspect of the inventive concept, an integrated circuit semiconductor device includes a plurality of fin-type active regions protruding from a substrate, extending in a first direction with respect to the substrate, and spaced apart from each other in a second direction that intersects the first direction; nano sheet stacking structures on the fin-type active regions; placeholders within the fin-type active regions; source and drain regions on the placeholders; a dielectric wall structure extending in the first direction and separating, in the second direction, a pair of the fin-type active regions, the nano sheet stacking structures thereon, the placeholders therein, and the source and drain regions thereon; field regions within trenches in the substrate that separate the fin-type active regions, the field regions each comprising a multi-insulating layer; and a plurality of gate structures extending in the second direction on the nano sheet stacking structures and spaced apart from each other in the first direction.

### BRIEF DESCRIPTION OF THE DRAWINGS

Embodiments will be more clearly understood from the following detailed description taken in conjunction with the accompanying drawings in which:

FIG. 1 is a layout diagram of an integrated circuit semiconductor device according to an embodiment;

FIG. 2 is a cross-sectional view taken along line A-A′ of FIG. 1;

FIG. 3 is an enlarged view of a portion of FIG. 2;

FIG. 4 is a cross-sectional view taken along line B-B′ of FIG. 1;

FIG. 5 is an enlarged view of a portion of FIG. 4;

FIG. 6 is a cross-sectional view of an integrated circuit semiconductor device according to an embodiment;

FIG. 7 is a cross-sectional view of an integrated circuit semiconductor device according to an embodiment; and

FIGS. 8 to 25 are cross-sectional views illustrating a method of manufacturing an integrated circuit semiconductor device, according to an embodiment.

### DETAILED DESCRIPTION OF EMBODIMENTS

Hereinafter, preferred embodiments will be described in detail with reference to the attached drawings. The embodiments herein may be implemented by only one of them, or more of the embodiments may be implemented by combining them. Therefore, the inventive concept is not interpreted as being limited to one embodiment.

In the present specification, the singular form of elements may include the plural form unless the context clearly indicates otherwise. In the present specification, the drawings are exaggerated to clearly describe the inventive concept. The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present.

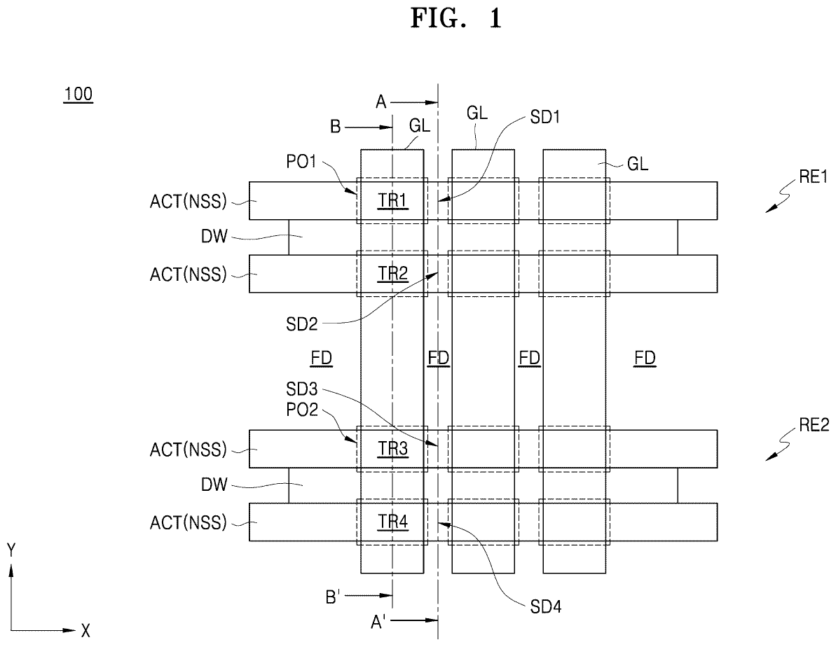

FIG. 1 is a layout diagram of an integrated circuit semiconductor device according to an embodiment.

In FIG. 1, an X direction may be a first horizontal direction, and a Y direction may be a second horizontal direction that intersects (e.g., is perpendicular to) the first horizontal direction. Hereinafter, a layout of an integrated circuit semiconductor device 100 is described in detail, however, the inventive concept is not limited to the layout of FIG. 1.

The integrated circuit semiconductor device 100 may include a first region RE1 and a second region RE2. In each of the first region RE1 and the second region RE2, the integrated circuit semiconductor device 100 may include a plurality of fin-type active regions ACT extending in the first horizontal direction (the X direction) and spaced apart from each other in the second horizontal direction (the Y direction). The fin-type active regions ACT may be P-type active regions or N-type active regions.

The integrated circuit semiconductor device 100 may include a plurality of gate structures GL extending in the second horizontal direction (the Y direction) perpendicular to the first horizontal direction (the X direction) and spaced apart from each other in the first horizontal direction (the X direction). The gate structures GL may each include a gate insulating layer and a gate electrode.

The integrated circuit semiconductor device 100 may further include nano sheet stacking structures NSS arranged on the fin-type active regions ACT. In the integrated circuit semiconductor device 100, the nano sheet stacking structures NSS may be positioned in overlapping portions PO1 and PO2 indicated by dotted lines where the fin-type active regions ACT and the gate structures GL intersect each other in a final structure. Components or layers described with reference to “overlap” in a particular direction may be at least partially obstructed by one another when viewed along a line extending in the particular direction or in a plane perpendicular to the particular direction. The gate structures GL may be arranged to cover the nano sheet stacking structures NSS. The term “covering” or “surrounding” or “filling” as may be used herein may not require completely covering or surrounding or filling the described elements or layers, but may, for example, refer to partially covering or surrounding or filling the described elements or layers, for example, with voids or other discontinuities throughout.

The integrated circuit semiconductor device 100 may include a dielectric wall structure DW extending in the first horizontal direction (the X direction) and positioned between the fin-type active regions ACT and between the nano sheet stacking structures NSS in the second horizontal direction (the Y direction). The dielectric wall structure DW may include an insulating wall structure.

The integrated circuit semiconductor device 100 may include field regions FD arranged between the fin-type active regions ACT to separate the fin-type active regions ACT from each other. The field regions FD may include a multi-insulating layer within a first trench formed in a substrate as described below. As used herein, a multi-insulating layer may refer to an insulating structure that includes different insulating materials, for example, two or more layers of different insulating materials.

In some embodiments, the multi-insulating layer may be a triple-insulating layer of a first field insulating layer, a second field insulating layer, and a third field insulating layer sequentially arranged within the first trench. The first field insulating layer, the second field insulating layer, and the third field insulating layer may be a first oxide layer, a first nitride layer, and a second oxide layer, respectively.

In some embodiments, the multi-insulating layer may be a double-insulating layer of a first field insulating layer and a second field insulating layer sequentially arranged within trenches. The first field insulating layer and the second field insulating layer may be a second oxide layer and a second nitride layer, respectively.

The fin-type active regions ACT are not exposed by the field regions FD during a manufacturing process, which may thus suppress the growth of parasitic conductive layers (or parasitic epilayers) on one sidewall of each of the fin-type active regions ACT. Accordingly, according to the integrated circuit semiconductor device 100 of the inventive concept, device performance or reliability may be improved by preventing short circuits between the gate structures GL. The term “exposed,” may be used to describe relationships between elements and/or certain intermediate processes in fabricating a completed semiconductor device, but may not necessarily require exposure of the particular region, layer, structure or other element in the context of the completed device.

In the first region RE1, first and second source and drain regions SD1 and SD2 may be formed at one side of the nano sheet stacking structures NSS arranged in the overlapping portion PO1 where the fin-type active regions ACT and the gate structures GL intersect each other. Accordingly, the first region RE1 may include a first nano sheet transistor TR1 and a second nano sheet transistor TR2.

The first nano sheet transistor TR1 and the second nano sheet transistor TR2 may include the fin-type active regions ACT and the gate structures GL. The first nano sheet transistor TR1 and the second nano sheet transistor TR2 may be a P-type transistor and an N-type transistor, respectively.

In the second region RE2, a third source and drain region SD3 and a fourth source and drain region SD4 may be formed at one side of the nano sheet stacking structures NSS arranged in the overlapping portion PO2 where the fin-type active regions ACT and the gate structures GL intersect each other. Accordingly, the second region RE2 may include a third nano sheet transistor TR3 and a fourth nano sheet transistor TR4.

The third nano sheet transistor TR3 and the fourth nano sheet transistor TR4 may include the fin-type active regions ACT and the gate structures GL. The third nano sheet transistor TR3 and the fourth nano sheet transistor TR4 may be a P-type transistor and an N-type transistor, respectively.

The integrated circuit semiconductor device 100 may include, in the overlapping portions PO1, PO2 where the fin-type active regions ACT and the gate structures GL intersect each other, the first to fourth nano sheet transistors TR1, TR2, TR3, TR4 including the nano sheet stacking structures NSS and the gate structures GL.

The first to fourth nano sheet transistors TR1, TR2, TR3, and TR4 may be three-dimensional transistors. The first to fourth nano sheet transistors TR1, TR2, TR3, and TR4 may include multi-bridge channel transistors (MBC) including the nano sheet stacking structures NSS and the gate structures GL.

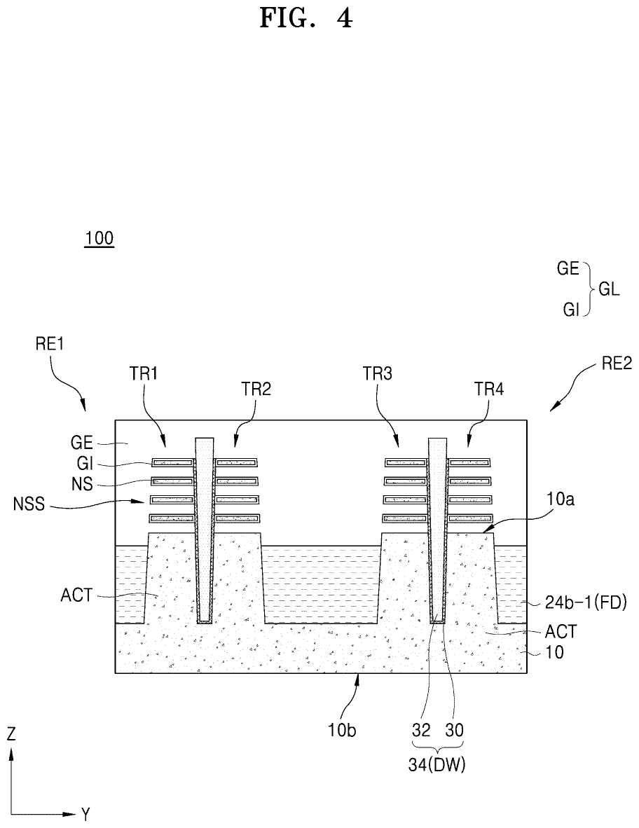

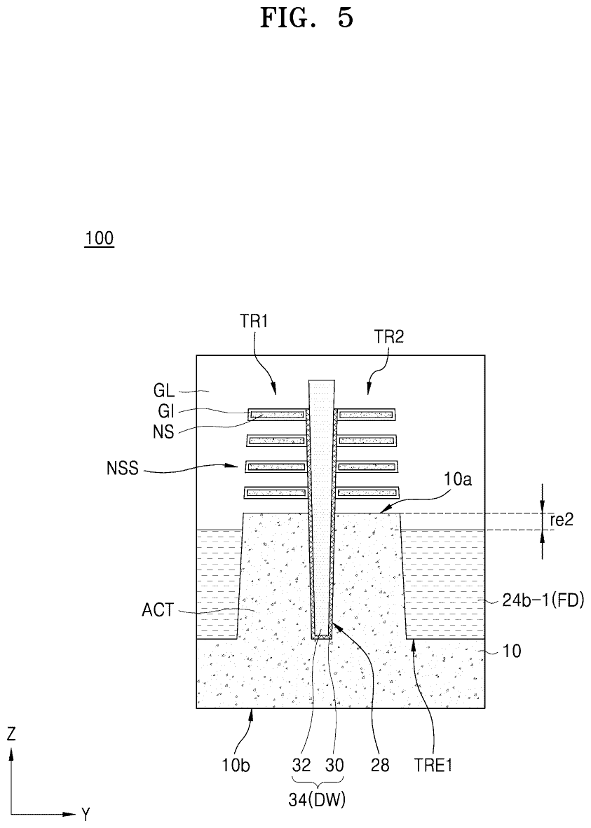

The integrated circuit semiconductor device 100 may have a dielectric wall structure DW arranged between the fin-type active regions ACT and between the nano sheet stacking structures NSS, as illustrated in FIGS. 4 and 5.

Accordingly, the first to fourth nano sheet transistors TR1, TR2, TR3, TR4 of the integrated circuit semiconductor device 100 may be forksheet type transistors. Forksheet type transistors may be transistors having shape of a combination of a fork and a sheet.

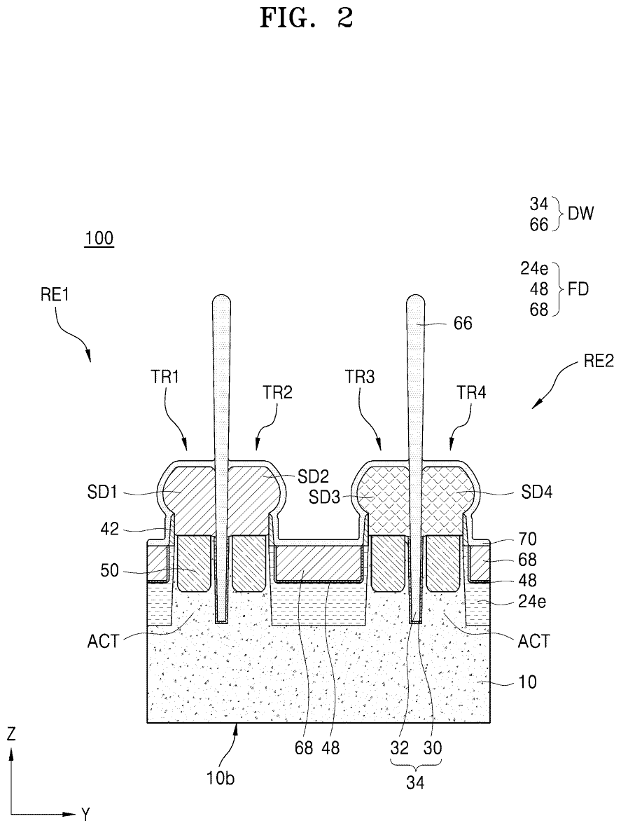

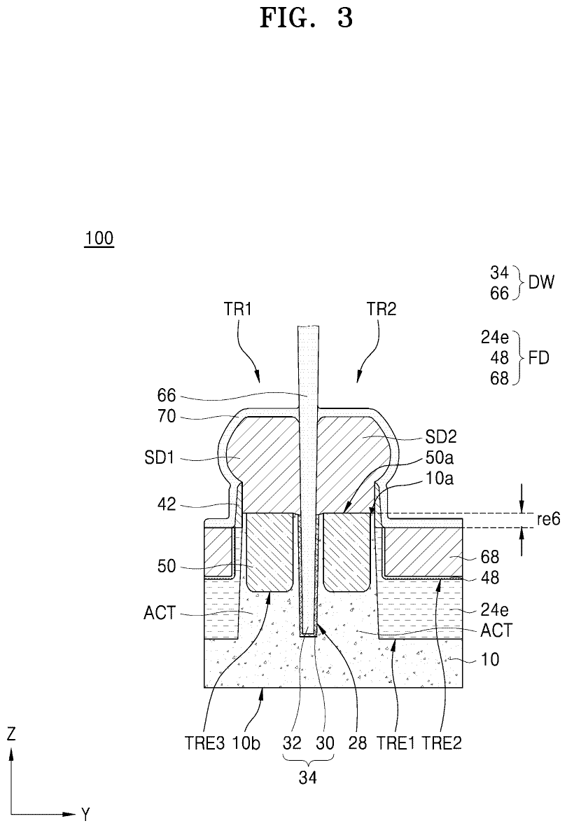

FIG. 2 is a cross-sectional view taken along line A-A′ of FIG. 1, and FIG. 3 is an enlarged view of a portion of FIG. 2.

In the drawings below, a Z direction may be a vertical direction perpendicular to a plane formed by the first horizontal direction (X direction) and the second horizontal direction (Y direction). The Z direction may be a direction perpendicular to a surface of a substrate 10.

FIG. 2 illustrates the first and second nano sheet transistors TR1, TR2 of the first region RE1 along line A-A′ of FIG. 1, and the third and fourth nano sheet transistors TR3, TR4 of the second region RE2 along line A-A′ of FIG. 1.

FIG. 3 is an enlarged view illustrating the first and second nano sheet transistors TR1, TR2 of the first region RE1 of FIG. 2. In a final structure of the integrated circuit semiconductor device 100 of FIG. 2, the nano sheet stacking structures (NSS of FIG. 1) and the gate structures GL on the fin-type active regions ACT along a cross-sectional line are not shown.

The integrated circuit semiconductor device 100 may include the substrate 10, the fin-type active regions ACT, placeholders 50, first to fourth source and drain regions SD1, SD2, SD3, SD4, and dielectric wall structures DW, and the field regions FD.

The substrate 10 may have a first side 10a and a second side 10b facing the first side 10a in an inverse vertical direction (−Z direction). The first side 10a may be referred to as a first surface, and the second side 10b may be referred to as a second surface, such that the first side/surface 10a is opposite the second side/surface 10b. The substrate 10 may also be referred to as a base layer. The substrate 10 may include a semiconductor such as Si or Ge, or a compound semiconductor such as SiGe, SiC, GaAs, InAs, or InP. In the present embodiment, a silicon substrate is used as the substrate 10.

The fin-type active regions ACT are recessed from a surface of the substrate 10, i.e., the first side 10a. That is, the fin-type active regions ACT protrude from the substrate 10 in a vertical (e.g., Z-) direction. The fin-type active regions ACT may be defined by the field regions FD. The fin-type active regions ACT may be spaced apart from each other in the second horizontal direction (Y direction) in the first region RE1 and the second region RE2.

The placeholders 50 are arranged within the fin-type active regions ACT in the first region RE1 and the second region RE2. The placeholders 50 may be arranged within a third trench TRE3 within the fin-type active regions ACT. The placeholders 50 may include an epi(taxial) layer doped with impurities. In some embodiments, the second surface 10b of the substrate 10 may be further etched through a CMP (chemical mechanical polishing) process. Then, at least one of the placeholders 50 may be removed to form a via hole. An insulating liner may be formed between the via hole and the fin-type active regions ACT.

A through via (i.e., back side via) may be formed in the via hole in which an insulating liner is formed. The through via (i.e., back side via) may be referred to as a through silicon via. The through via (i.e., back side via) may be formed to provide electrical connection to the source and drain regions SD1, SD2, SD3, and/or SD4. A back side wiring layer may be formed on the second surface 10b of the substrate 10. The through via (i.e., back side via) may be electrically connected to the back side wiring layer.

In some embodiments, the second surface 10b of the substrate 10 may be further etched through a CMP (chemical mechanical polishing) process. Then, the fin-type active regions ACT may be removed through an etching process. The portion from which the fin-type active regions ACT are removed may be filled with an insulating pattern. That is, the fin-type active regions ACT may be replaced with an insulating pattern.

The first to fourth source and drain regions SD1, SD2, SD3, and SD4 may be arranged on the placeholders 50 on the fin-type active regions ACT in the first region RE1 and the second region RE2.

The dielectric wall structure DW may be arranged to separate between the fin-type active regions ACT, between the placeholders 50, between the first and second source and drain regions SD1 and SD2, and between the third and fourth source and drain regions SD3 and SD4 in the first region RE1 and the second region RE2. The dielectric wall structure DW may include a dielectric insulating structure. The dielectric wall structure DW may include a first dielectric wall structure 34 and a second dielectric wall structure 66. The second dielectric wall structure 66 may be etched in a subsequent process as needed.

The first dielectric wall structure 34 may include a wall liner insulating layer 30 formed within a first active hole 28 formed within the fin-type active regions ACT, and a first wall insulating layer 32 embedded within the first active hole 28 within the wall liner insulating layer 30. The second dielectric wall structure 66 may be formed on the first wall insulating layer 32 and may include a second wall insulating layer that separates between the first and second source and drain regions SD1 and SD2, and between the third and fourth source and drain regions SD3 and SD4. The field regions FD and the dielectric wall structures DW are arranged on both (e.g., opposing) sides of the fin-type active regions ACT. For example, a pair of the fin-type active regions ACT may include outer sidewalls having the field regions FD thereon, and inner sidewalls having the dielectric wall structures DW thereon. The outer sidewalls may be on opposing or outward-facing sides of a pair of fin-type active regions ACT, while the inner sidewalls may be on adjacent or inward-facing sides of a pair of fin-type active regions ACT.

The field regions FD may be arranged to separate the fin-type active regions ACT. In some embodiments, a surface of the field regions FD may be recessed from or relative to the side 10a of the substrate 10 or a surface 50a of the placeholders 50 to a sixth recess depth re6. The sixth recess depth re6 may be adjusted as needed. The field regions FD may include a multi-insulating layer arranged within a first trench TRE1 formed in the substrate 10. The first trench TRE1 may be a device isolation trench.

The multi-insulating layer constituting the field regions FD may be a triple insulating layer of a first field insulating layer 24c, a second field insulating layer 48, and a third field insulating layer 68 sequentially arranged or stacked within the first trench TRE1. The first field insulating layer 24c, the second field insulating layer 48, and the third field insulating layer 68 may be a first oxide layer, a first nitride layer, and a second oxide layer, respectively.

The second field insulating layer 48 may be arranged within a second trench TRE2 within the first trench TRE1. A thickness of the second field insulating layer 48 may be less than respective thicknesses of the first field insulating layer 24c and the third field insulating layer 68.

The integrated circuit semiconductor device 100 may further include spacers 42 arranged on one sides (e.g., on the outer sidewalls) of the fin-type active regions ACT. The spacers 42, the field regions FD, and the dielectric wall structures DW may be arranged on one sides (e.g., on the outer sidewalls) of the fin-type active regions ACT. On both sides of the fin-type active regions ACT, the spacers 42 and the field regions FD and the dielectric wall structures DW may be arranged.

The integrated circuit semiconductor device 100 may further include a cover layer 70 covering the first to fourth source and drain regions SD1, SD2, SD3, and SD4, the spacers 42, and the field regions FD.

In the integrated circuit semiconductor device 100, the fin-type active regions ACT may be covered or otherwise controlled or protected from being exposed by the field regions FD during a manufacturing process, thereby suppressing the growth of a parasitic conductive layer (or parasitic epilayer) on one sidewall (e.g., an outer sidewall) of each of the fin-type active regions ACT. Accordingly, as described above, according to the integrated circuit semiconductor device 100 of the inventive concept, device performance or reliability may be improved by preventing short circuits between the gate structures GL.

FIG. 4 is a cross-sectional view taken along line B-B′ of FIG. 1, and FIG. 5 is an enlarged view of a portion of FIG. 4.

The details described with reference to FIGS. 1, 2 and 3 are briefly described or omitted with reference to FIGS. 4 and 5. FIG. 4 illustrates the first and second nano sheet transistors TR1 and TR2 of the first region RE1 along line B-B′ of FIG. 1, and the third and fourth nano sheet transistors TR3 and TR4 of the second region RE2 along line B-B′ of FIG. 1.

FIG. 5 is an enlarged view illustrating the first and second nano sheet transistors TR1 and TR2 of the first region RE1 of FIG. 4. In a final structure of the integrated circuit semiconductor device 100 of FIG. 4, the placeholders 50 and the first to fourth source and drain regions SD1, SD2, SD3, and SD4 are not shown along a cross-sectional line thereof.

The integrated circuit semiconductor device 100 may include the substrate 10, the fin-type active regions ACT, the nano sheet stacking structures NSS, the dielectric wall structures DW, the field regions FD, and the gate structures GL.

The substrate 10 may have the first side 10a and the second side 10b facing the first side 10a in an inverse vertical direction (−Z direction), such that the first side/surface 10a is opposite the second side/surface 10b. The fin-type active regions ACT are recessed from a surface of the substrate 10, i.e., the first side 10a, so as to protrude from the substrate 10 in the vertical (e.g., Z-) direction. The fin-type active regions ACT may be defined by the field regions FD. The fin-type active regions ACT may be spaced apart from each other in the second horizontal direction (Y direction) in the first region RE1 and the second region RE2.

In the first region RE1 and the second region RE2, the nano sheet stacking structures NSS are arranged on the fin-type active regions ACT. The nano sheet stacking structures NSS may include a plurality of nano sheets NS arranged vertically (e.g., stacked in the Z-direction) on the fin-type active regions ACT.

In the first region RE1 and the second region RE2, a gate insulating layer GI and a gate electrode GE surrounding the nano sheets NS may be included. The gate structures GL may include the gate insulating layer GI and the gate electrode GE. The gate structures GL may be arranged to extend in the second horizontal direction and cover the nano sheet stacking structures NSS.

The dielectric wall structure DW may be arranged to separate between the fin-type active regions ACT and between the nano sheet stacking structures NSS in the first region RE1 and the second region RE2. The dielectric wall structure DW may include a dielectric insulating structure. The dielectric wall structure DW may include the first dielectric wall structure 34.

The first dielectric wall structure 34 may include the wall liner insulating layer 30 formed within the first active hole 28 formed within the fin-type active regions ACT, and the first wall insulating layer 32 embedded within the first active hole 28 within the wall liner insulating layer 30.

The field regions FD are arranged on one sides (e.g. on outer sidewalls) of the fin-type active regions ACT. The field regions FD and the dielectric wall structures DW may be arranged on both (e.g., opposing) sides of the fin-type active regions ACT, respectively.

The field regions FD may be arranged to separate the fin-type active regions ACT. In some embodiments, surfaces of the field regions FD may be recessed from the side 10a of the substrate 10 to a second recess depth re2. The second recess depth re2 may be adjusted as needed. The field regions FD may include a multi-insulating layer arranged within the first trench TRE1 formed in the substrate 10.

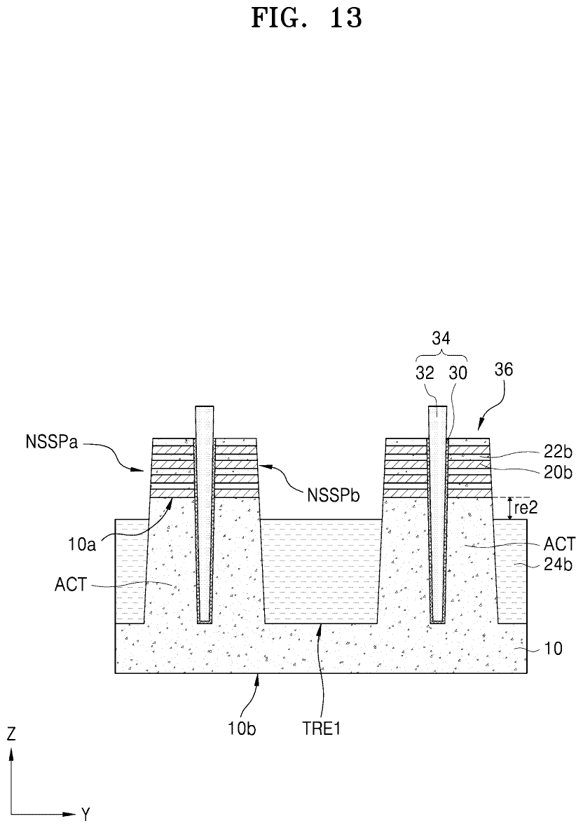

A single insulating layer constituting the field regions FD may be a field insulating layer 24b-1 arranged within the first trench TRE1. The field insulating layer 24b-1 may be an oxide layer. The field insulating layer 24b-1 may correspond to a second field sub-insulating pattern 24b of FIG. 13, which will be described later.

The fin-type active regions ACT may be covered or otherwise controlled or protected so as not to be exposed by the field regions FD during a manufacturing process, which may thus suppress the growth of parasitic conductive layers (or parasitic epilayers) on one sidewall of each of the fin-type active regions ACT. Thus, as described above, device performance or reliability may be improved by preventing short circuits between the gate structures GL.

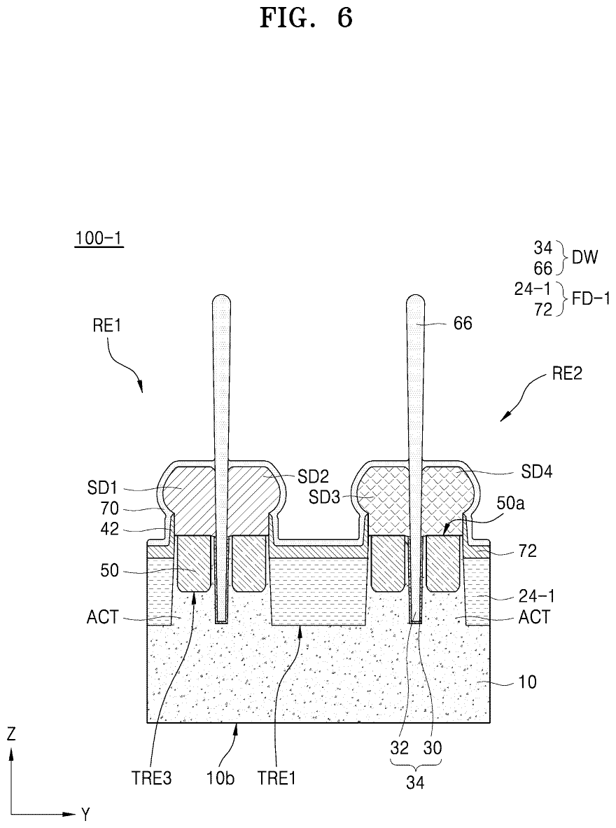

FIG. 6 is a cross-sectional view of an integrated circuit semiconductor device according to an embodiment.

An integrated circuit semiconductor device 100-1 may be the same as or similar to the integrated circuit semiconductor device 100 of FIGS. 2 and 3 except that the structure of field regions FD-1 is different. In FIG. 6, the same reference numerals as those of FIGS. 2 and 3 indicate the same members. In FIG. 6, the details described with reference to FIGS. 2 and 3 are briefly described or omitted.

The integrated circuit semiconductor device 100-1 may include the substrate 10, the fin-type active regions ACT, the placeholders 50, the first to fourth source and drain regions SD1, SD2, SD3, and SD4, and the dielectric wall structures DW, and the field regions FD-1.

The fin-type active regions ACT are recessed from a surface of the substrate 10, i.e., the first side 10a, such that the fin-type active regions ACT protrude from the substrate 10. The fin-type active regions ACT may be defined by the field regions FD-1. The placeholders 50 are arranged within the fin-type active regions ACT in the first region RE1 and the second region RE2. The placeholders 50 may be arranged within the third trench TRE3 within the fin-type active region ACT.

The first to fourth source and drain regions SD1, SD2, SD3, and SD4 may be arranged on the placeholders 50 on the fin-type active regions ACT in the first region RE1 and the second region RE2. The dielectric wall structure DW may be arranged in the first region RE1 and the second region RE2 to separate between the fin-type active regions ACT, between the placeholders 50, between the first and second source and drain regions SD1 and SD2, and between the third and fourth source and drain regions SD3 and SD4. The dielectric wall structure DW may include the first dielectric wall structure 34 and the second dielectric wall structure 66.

The field regions FD-1 may be arranged to separate the fin-type active regions ACT. A surface of the field regions FD-1 may be recessed from or relative to the side 10a of the substrate 10 or the surface 50a of the placeholders 50. The field regions FD-1 may include a multi-insulating layer arranged within the first trench TRE1 formed in the substrate 10.

The multi-insulating layer constituting the field regions FD-1 may be a double layer of a first field insulating layer 24-1 and a second field insulating layer 72 sequentially arranged or stacked within the first trench TRE1. The first field insulating layer 24-1 and the second field insulating layer 72 may be a first oxide layer and a first nitride layer, respectively. A thickness of the second field insulating layer 72 may be less than a thickness of the first field insulating layer 24-1.

The integrated circuit semiconductor device 100-1 may further include the spacers 42 arranged on one sides (e.g., on outer sidewalls) of the fin-type active regions ACT. The integrated circuit semiconductor device 100-1 may further include the cover layer 70 covering the first to fourth source and drain regions SD1, SD2, SD3, and SD4, the spacers 42, and the field regions FD-1.

In the integrated circuit semiconductor device 100-1, the fin-type active regions ACT may be covered or otherwise protected or controlled so as not to be exposed by the field regions FD-1 during a manufacturing process, thereby suppressing the growth of a parasitic conductive layer (or parasitic epilayer) on one sidewall of each of the fin-type active regions ACT. Accordingly, as described above, according to the integrated circuit semiconductor device 100-1 of the inventive concept, device performance or reliability may be improved by preventing short circuits between the gate structures GL.

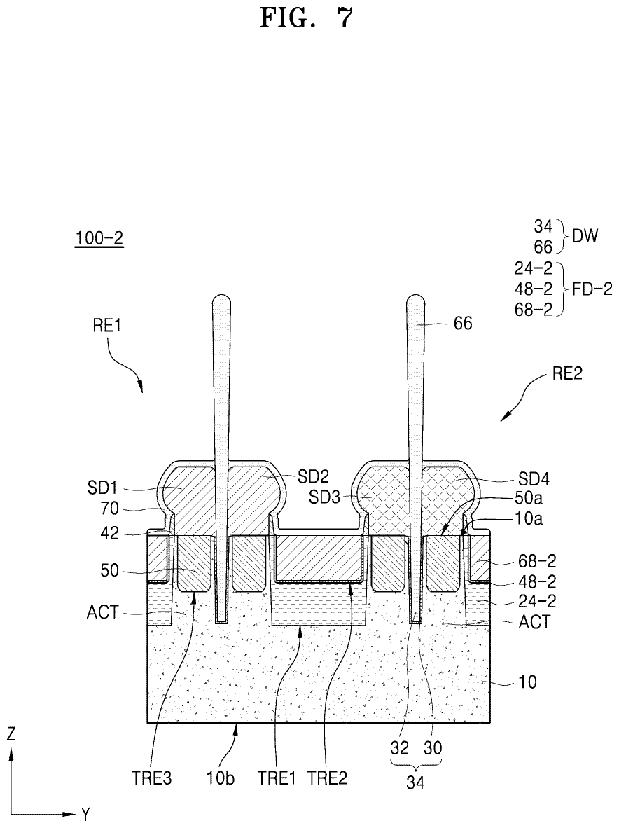

FIG. 7 is a cross-sectional view of an integrated circuit semiconductor device according to an embodiment.

An integrated circuit semiconductor device 100-2 may be the same as or similar to the integrated circuit semiconductor device 100 of FIGS. 2 and 3 except that the structure of field regions FD-2 is different. In FIG. 7, the same reference numerals as those of FIGS. 2 and 3 denote the same members. In FIG. 7, the details described with reference to FIGS. 2 and 3 are briefly described or omitted.

The integrated circuit semiconductor device 100-2 may include the substrate 10, the fin-type active regions ACT, the placeholders 50, the first to fourth source and drain regions SD1, SD2, SD3, and SD4, and the dielectric wall structures DW, and the field regions FD-2.

The fin-type active regions ACT are recessed from a surface of the substrate 10, i.e., the first side 10a, so as to protrude from the substrate 10. The fin-type active regions ACT may be defined by the field regions FD-2. The placeholders 50 are arranged within the fin-type active regions ACT in the first region RE1 and the second region RE2. The placeholders 50 may be arranged within the third trench TRE3 within the fin-type active region ACT.

The first to fourth source and drain regions SD1, SD2, SD3, and SD4 may be arranged on the placeholders 50 on the fin-type active regions ACT in the first region RE1 and the second region RE2. The dielectric wall structure DW may be arranged in the first region RE1 and the second region RE2 to separate between the fin-type active regions ACT, between the placeholders 50, between the first and second source and drain regions SD1 and SD2, and between the third and fourth source and drain regions SD3 and SD4. The dielectric wall structure DW may include the first dielectric wall structure 34 and the second dielectric wall structure 66.

The field regions FD-2 may be arranged to separate the fin-type active regions ACT. A surface of the field regions FD-2 may be coplanar with the side 10a of the substrate 10 or the surface 50a of the placeholders 50. The field regions FD-2 may include a multi-insulating layer arranged within the first trench TRE1 formed in the substrate 10.

The multi-insulating layer constituting the field regions FD-2 may be a triple insulating layer of a first field insulating layer 24-2, a second field insulating layer 48-2, and a third field insulating layer 68-2 sequentially arranged or stacked within the first trench TRE1. The first field insulating layer 24-2, the second field insulating layer 48-2, and the third field insulating layer 68-2 may be a first oxide layer, a first nitride layer, and a second oxide layer, respectively. A thickness of the second field insulating layer 48-2 may be less than thicknesses of the first field insulating layer 24-2 and the third field insulating layer 68-2.

The integrated circuit semiconductor device 100-2 may further include the spacers 42 arranged on one sides (e.g., on outer sidewalls) of the fin-type active regions ACT. The integrated circuit semiconductor device 100-2 may further include the cover layer 70 covering the first to fourth source and drain regions SD1, SD2, SD3, and SD4, the spacers 42, and the field regions FD-2.

In the integrated circuit semiconductor device 100-2, the fin-type active regions ACT may be covered or otherwise protected or controlled so as not to be exposed by the field regions FD-2 during a manufacturing process, thereby suppressing the growth of a parasitic conductive layer (or parasitic epilayer) on one sidewall of each of the fin-type active regions ACT.

Accordingly, as described above, according to the integrated circuit semiconductor device 100-2 of the inventive concept, device performance or reliability may be improved by preventing short circuits between the gate structures GL.

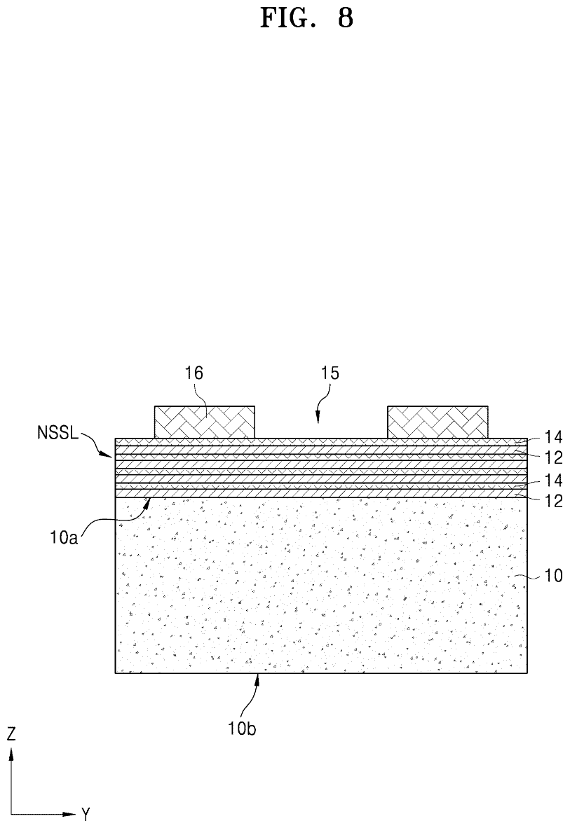

FIGS. 8 to 25 are cross-sectional views illustrating a method of manufacturing an integrated circuit semiconductor device, according to an embodiment.

FIGS. 8 to 25 are cross-sectional views for describing a method of manufacturing the integrated circuit semiconductor device 100 of FIGS. 2 and 3. In FIGS. 8 to 25, the same reference numerals as those of FIGS. 2 and 3 denote the same elements. In FIGS. 8 to 25, the details described with reference to FIGS. 2 and 3 are briefly described or omitted.

Referring to FIG. 8, the substrate 10 is prepared. The substrate 10 may also be referred to as a base layer. The substrate 10 may have the first side 10a and the second side 10b. The first side 10a may be a front surface, and the second side 10b may be a back surface that is opposite the front surface.

The substrate 10 may include a semiconductor such as Si or Ge, or a compound semiconductor such as SiGe, SiC, GaAs, InAs, or InP. In some embodiments, the substrate may include at least one of a Group III-V material and a Group IV material.

The Group III-V material may be a binary, ternary, or quaternary compound including at least one Group III element and at least one Group V element. The Group III-V material may be a compound including at least one element among In, Ga, and Al as a Group III element and at least one element among As, P, and Sb as a Group V element.

For example, the Group III-V material may be selected from InP, InzGa1−zAs (0≤z≤1), and AlzGa1−zAs (0≤z≤1). The binary compound may be, for example, one of InP, GaAs, InAs, InSb, and GaSb. The ternary compound may be any one of InGaP, InGaAs, AlInAs, InGaSb, GaAsSb, and GaAsP. The Group IV element may be Si or Ge. However, Group III-V materials and Group IV materials that may be used in the integrated circuit semiconductor devices according to the inventive concept are not limited to those examples provided above.

Group III-V materials and Group IV materials such as Ge may be used as channel materials to manufacture low-power, high-speed transistors. A high-performance transistor may be formed using a semiconductor substrate including a Group III-V material, such as GaAs, which has higher electron mobility than a Si substrate, and a semiconductor substrate including a semiconductor material, such as Ge, which has higher hole mobility than a Si substrate. In some embodiments, the substrate 10 may have a silicon on insulator (SOI) structure. In the present embodiment, as the substrate 10, a silicon substrate is used.

The semiconductor stacking material layer NSSL may be formed by alternately stacking, on the substrate 10, a sacrificial semiconductor layer 12 and a semiconductor layer 14 for nano sheets. The semiconductor stacking material layer NSSL includes a plurality of sacrificial semiconductor layers 12 and a plurality of semiconductor layers 14 for nano sheets. In the present embodiment, four sacrificial semiconductor layers 12 and four semiconductor layers 14 for nano sheets are formed on the substrate 10, but the inventive concept is not limited thereto.

The semiconductor stacking material layer NSSL is formed on the first side 10a of the substrate 10. The sacrificial semiconductor layers 12 and the semiconductor layers 14 for nano sheets that constitute the semiconductor stacking material layer NSSL may be formed by an epitaxial growth method. The sacrificial semiconductor layers 12 and the semiconductor layers 14 for nano sheets may include different semiconductor materials.

In some embodiments, the sacrificial semiconductor layers 12 may include SiGe and the semiconductor layers 14 for nano sheets may include Si, but the inventive concept is not limited thereto. The sacrificial semiconductor layers 12 may include a material that is well etched or has a high etch selectivity with respect to the semiconductor layers 14 for nano sheets. The sacrificial semiconductor layers 12 and the semiconductor layers 14 for nano sheets may both be formed with the same thickness, but the inventive concept is not limited thereto.

First mask patterns 16 are formed spaced apart from each other on the semiconductor stacking material layer NSSL. A first opening 15 may be formed between the first mask patterns 16.

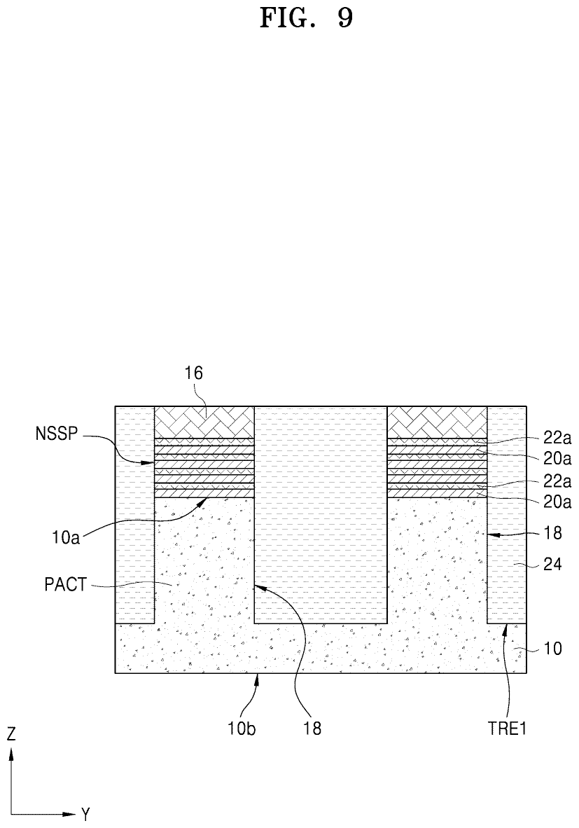

Referring to FIG. 9, the first mask patterns (16 of FIG. 8) are used as etching masks to etch a portion of each of the semiconductor stacking material layer NSSL and the substrate 10 to form preliminary fin-type active regions PACT and the first trench TRE1. The preliminary fin-type active regions PACT may each have one sidewall 18. The first trench TRE1 may be a device isolation trench. Accordingly, a preliminary semiconductor stack pattern NSSP may be formed on the preliminary fin-type active regions PACT.

The preliminary semiconductor stack pattern NSSP may include preliminary semiconductor patterns 20a and preliminary nano sheets 22a. The first trench TRE1 may be formed inside the preliminary semiconductor stack pattern NSSP and inside the preliminary fin-type active regions PACT. The first trench TRE1 may include a region formed under the first side 10a of the substrate 10.

Next, a first field insulating material layer 24 is buried within the first trench TRE1. The first field insulating material layer 24 may be formed by sufficiently filling the first trench TRE1 with an insulating material and then planarizing the insulating material by using a chemical mechanical polishing process and by using the first mask patterns 16 as an etching stop point. The first field insulating material layer 24 may be formed on one sidewall 18 (e.g., an outer sidewall) of the preliminary fin-type active regions PACT. The first field insulating material layer 24 may include an oxide layer.

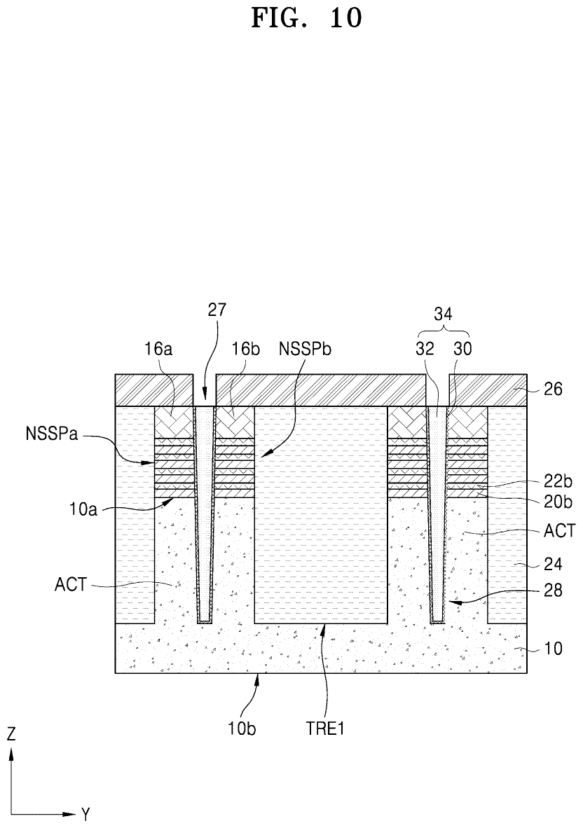

Referring to FIG. 10, second mask patterns 26 positioned apart from each other are formed on the first field insulating material layer 24 and the first mask patterns (16 of FIG. 8). A second opening 27 may be formed between the second mask patterns 26. The second mask patterns 26 may include the second openings 27 exposing the first mask patterns (16 in FIG. 8).

Using the second mask patterns 26 as an etching mask, the preliminary semiconductor stacking pattern (NSSP of FIG. 9) and the preliminary fin-type active regions PACT are etched to form the fin-type active regions ACT and the first active hole 28. The first active hole 28 may be an active trench. Accordingly, semiconductor stacking patterns NSSPa, NSSPb may be formed on the fin-type active regions ACT. First sub-mask patterns 16a, 16b may be formed on the semiconductor stacking patterns NSSPa, NSSPb.

The semiconductor stacking patterns NSSPa, NSSPb may include semiconductor patterns 20b and nano sheets 22b. The first active hole 28 may be formed inside the semiconductor stacking patterns NSSPa, NSSPb and inside the fin-type active regions ACT, exposing inner sidewalls thereof. The first active hole 28 may include a region formed below the first side 10a of the substrate 10.

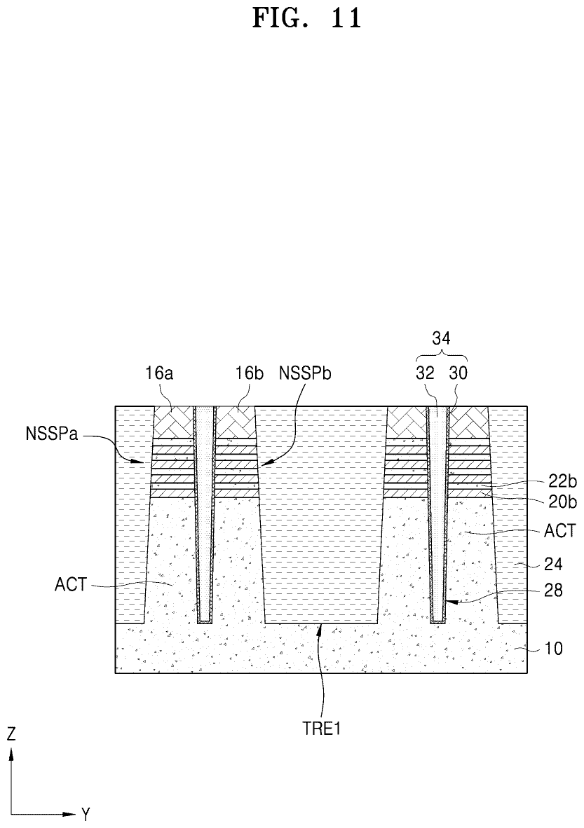

Referring to FIGS. 10 and 11, after removing the second mask patterns 26, the first dielectric wall structure 34 is formed within the first active hole 28. The first dielectric wall structure 34 may be formed by forming a liner insulating material layer and a first insulating material layer within the first active hole 28, and then planarizing the liner insulating material layer and the first insulating material layer by using a chemical mechanical polishing process and using the first sub-mask patterns 16a, 16b as an etching stop point. The first dielectric wall structure 34 may include the wall liner insulating layer 30 formed within the first active hole 28, and the first wall insulating layer 32 embedded within the first active hole 28 within the wall liner insulating layer 30.

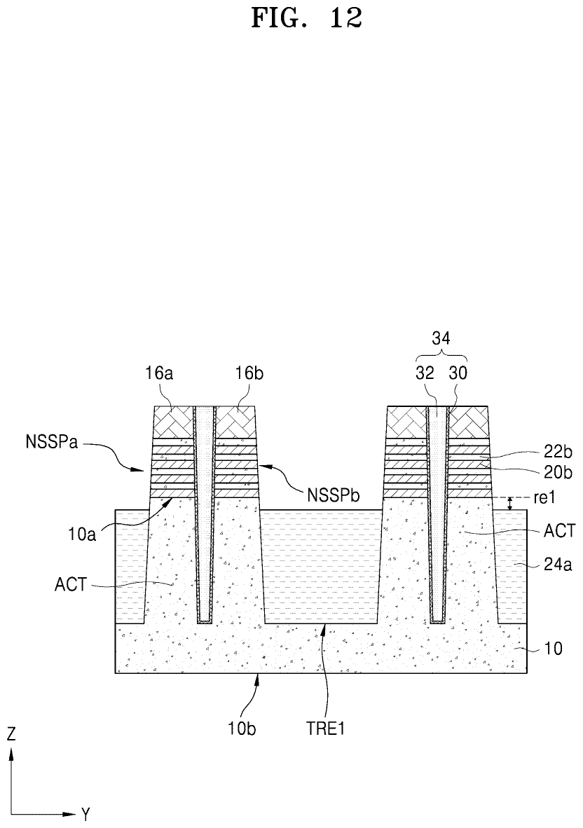

Referring to FIGS. 12 and 13, as illustrated in FIG. 12, the first field insulating material layer 24 is etched back from surfaces of the first sub-mask patterns 16a, 16b to form a first sub-field insulating pattern 24a. The first field sub-insulating pattern 24a may be recessed to a first depth re1 from surfaces of the fin-type active regions ACT or the side 10a of the substrate 10.

According to the formation of the first field sub-insulating pattern 24a, the semiconductor stacking patterns NSSPa, NSSPb may be exposed to the outside. The semiconductor patterns 20b and nano sheets 22b constituting the semiconductor stacking patterns NSSPa, NSSPb may be exposed to the outside. However, a majority (or up to all) of the outer sidewalls (18 in FIG. 9) may be covered or otherwise protected by the first sub-field insulating pattern 24a.

As illustrated in FIG. 13, the first sub-mask patterns 16a, 16b are removed by etching. The first field sub-insulating pattern (24a in FIG. 12) formed on one sidewalls (e.g., the outer sidewalls) of the fin-type active regions ACT during the removal process of the first sub-mask patterns 16a, 16b may become the second field sub-insulating pattern 24b.

The second field sub-insulating pattern 24b may be recessed to a second depth re2 from the surface of the fin-type active regions ACT or the side 10a of the substrate 10. An upper portion of the first dielectric wall structure 34 may be exposed according to the formation of the second field sub-insulating pattern 24b. Spatially relative terms such as “above,” “upper,” “upper portion,” “upper surface,” “below,” “lower,” “lower portion,” “lower surface,” “side surface,” and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features.

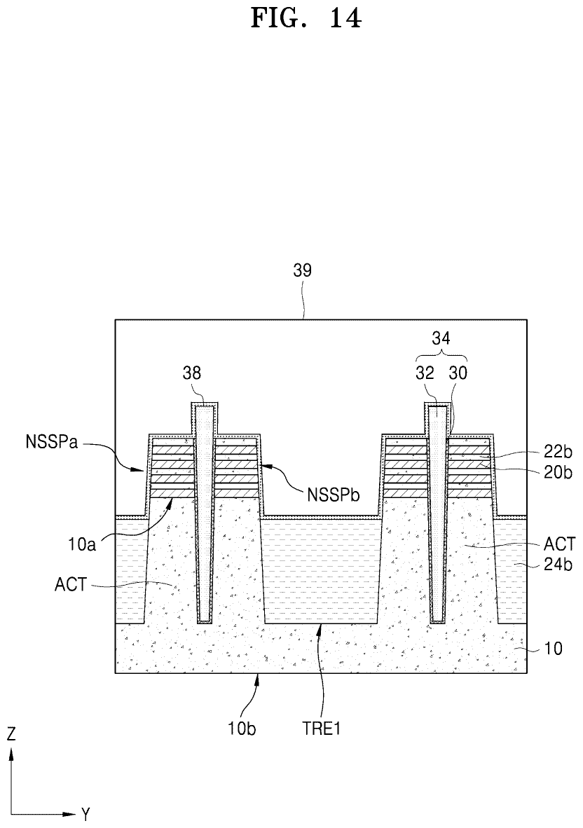

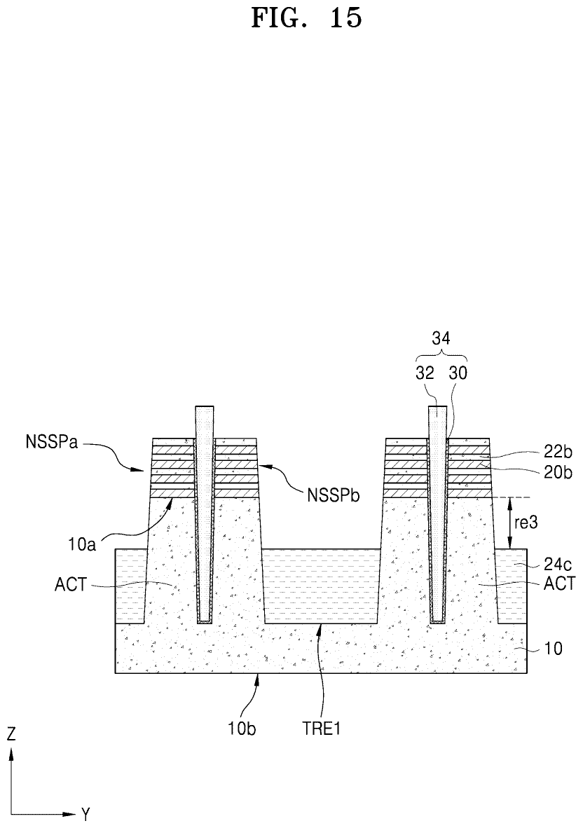

Referring to FIGS. 14 and 15, a first capping insulating layer 38 is formed on the semiconductor stacking patterns NSSPa, NSSPb, the second field sub-insulating pattern 24b and the first dielectric wall structure 34, as illustrated in FIG. 14. The first capping insulating layer 38 may include an oxide layer. Further, a third mask pattern 39 is formed on the first capping insulating layer 38. The third mask pattern 39 may be a pattern for forming the gate structures GL of FIGS. 4 and 5.

As illustrated in FIG. 15, the third mask pattern 39 and the first capping insulating layer 38 are removed by an etching process. When the third mask pattern 39 and the first capping insulating layer 38 are removed by an etching process, the second field sub-insulating pattern (24b in FIG. 14) formed on one sidewall (e.g., an outer sidewall) of the fin-type active regions ACT may become a third field sub-insulating pattern 24c. The third field sub-insulating pattern 24c may be recessed to a third depth re3 from the surface of the fin-type active regions ACT or the side 10a of the substrate 10.

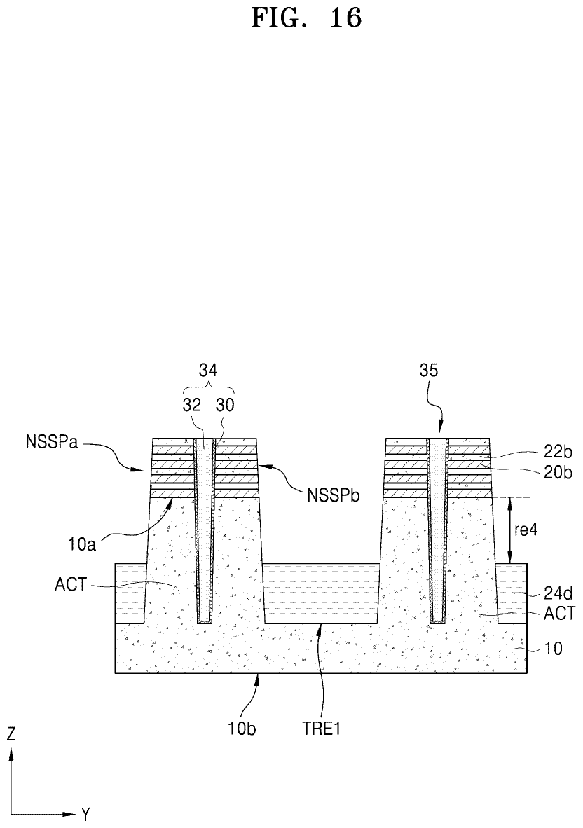

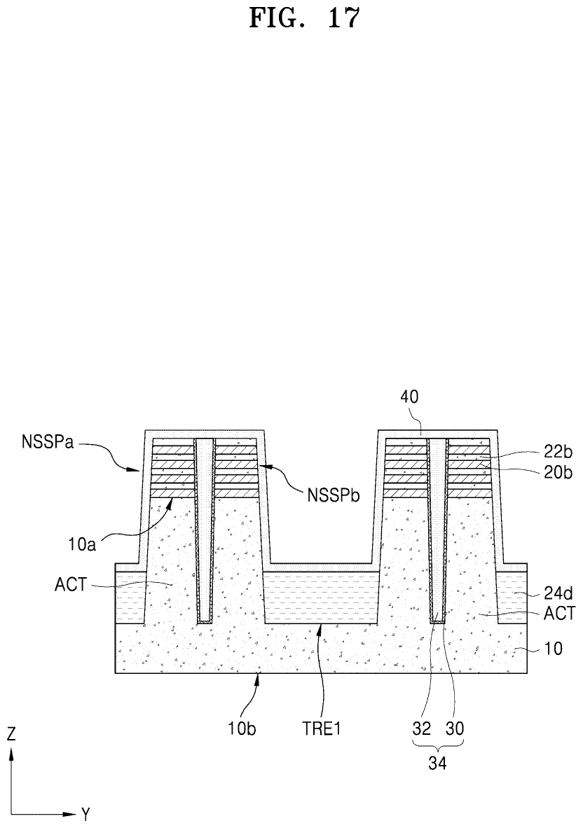

Referring to FIGS. 16 and 17, an upper portion of the first dielectric wall structure 34 is removed by an etching process as illustrated in FIG. 16. When the upper portion of the first dielectric wall structure 34 is removed, an upper surface of the first dielectric wall structure 34 may be coplanar with upper surfaces of the semiconductor stacking patterns NSSPa, NSSPb.

When the upper portion of the first dielectric wall structure 34 is removed by an etching process, the third field insulating pattern (24c in FIG. 15) formed on one sidewall (e.g., an outer sidewall) of the fin-type active regions ACT may become a fourth field sub-insulating pattern 24d. The fourth field sub-insulating pattern 24d may be recessed to a fourth depth re4 from the surface of the fin-type active regions ACT or the side 10a of the substrate 10.

As illustrated in FIG. 17, a spacer insulating layer 40 is formed on the semiconductor stacking patterns NSSPa, NSSPb, the fourth field sub-insulating pattern 24d, and the first dielectric wall structure 34. The spacer insulating layer 40 may be formed as a single layer or multiple layers. In some embodiments, the spacer insulating layer 40 may include a triple layer of an oxide layer, a nitride layer, and an oxide layer. The spacer insulating layer 40 may be formed on one sidewall of the gate structures GL of FIGS. 4 and 5.

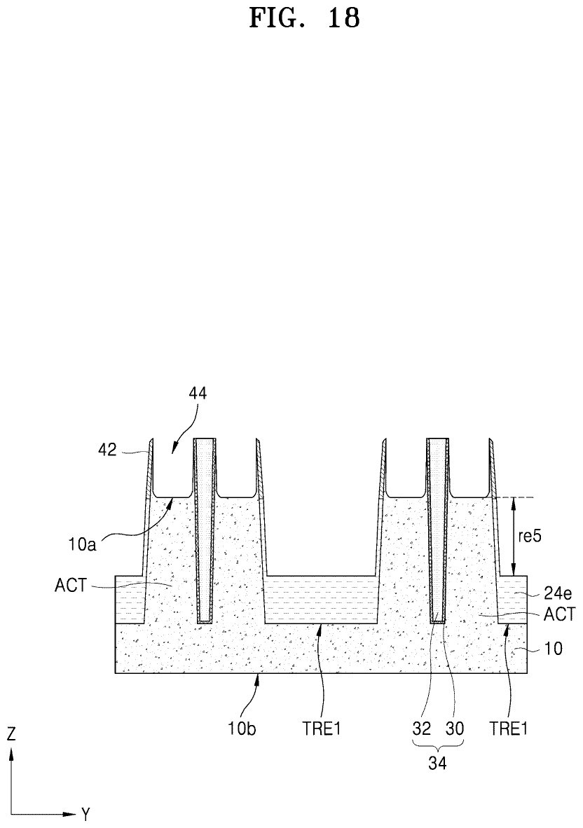

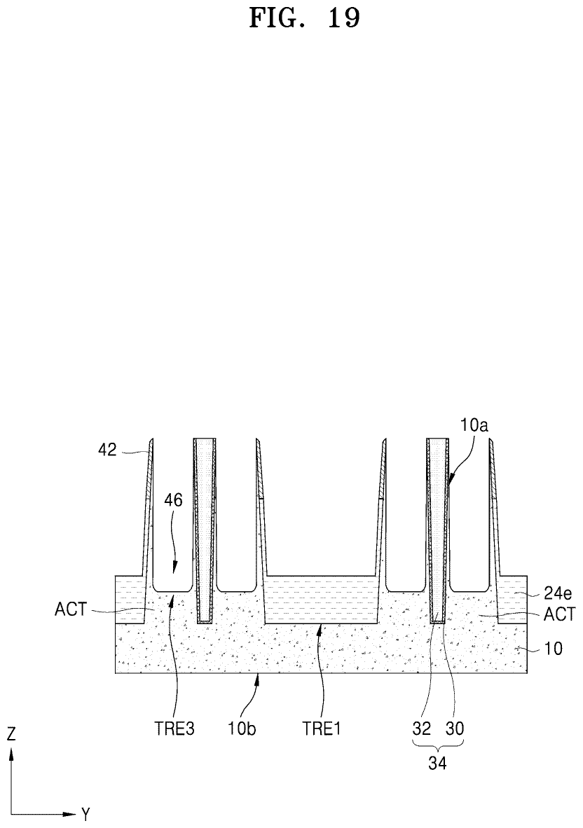

Referring to FIGS. 18 and 19, as illustrated in FIG. 18, the spacer insulating layer 40 is etched to form the spacers 42. The spacers 42 may be formed on one sides of the semiconductor stacking patterns NSSPa, NSSPb. When removing the semiconductor stacking patterns NSSPa, NSSPb in a post-process, the spacers 42 may be formed on one sides (e.g., on the outer sidewalls) of the fin-type active regions ACT.

In some embodiments, the spacer insulating layer 40 may be removed from or left on the one sidewall of each of the fin-type active regions ACT during the formation of the spacers 42. The spacer insulating layer 40 may be included in a second field insulating layer through a post-process.

Subsequently, the semiconductor stacking patterns NSSPa, NSSPb may be removed by an etching process to expose the surfaces of the fin-type active regions ACT as illustrated by reference numeral 44. When the semiconductor stacking patterns NSSPa, NSSPb are removed by an etching process, the fourth field sub-insulating pattern (24d in FIG. 17) formed on one sidewall (e.g., the outer sidewalls) of each of the fin-type active regions ACT may become a fifth field sub-insulating pattern 24c. The fifth field sub-insulating pattern 24e may be recessed to a fifth depth re5 from the surface of the fin-type active regions ACT or the side 10a of the substrate 10.

As illustrated in FIG. 19, the fin-type active regions ACT between the spacers 42 and the first dielectric wall structure 34 are additionally etched to form a third trench TRE3, as indicated by reference numeral 46. The fin-type active regions ACT, the surfaces of which are exposed, are additionally etched to form the third trench TRE3. The third trench TRE3 may be shallower than the first trench TRE1. In some embodiments, the fifth field sub-insulating pattern 24c may be additionally etched during the etching of the third trench TRE3. The fifth field sub-insulating pattern 24e may ultimately become a first field insulating layer.

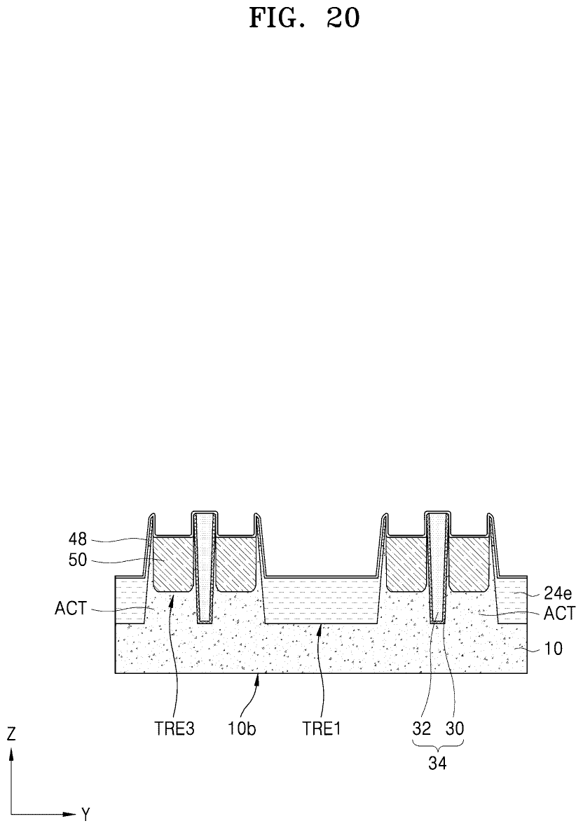

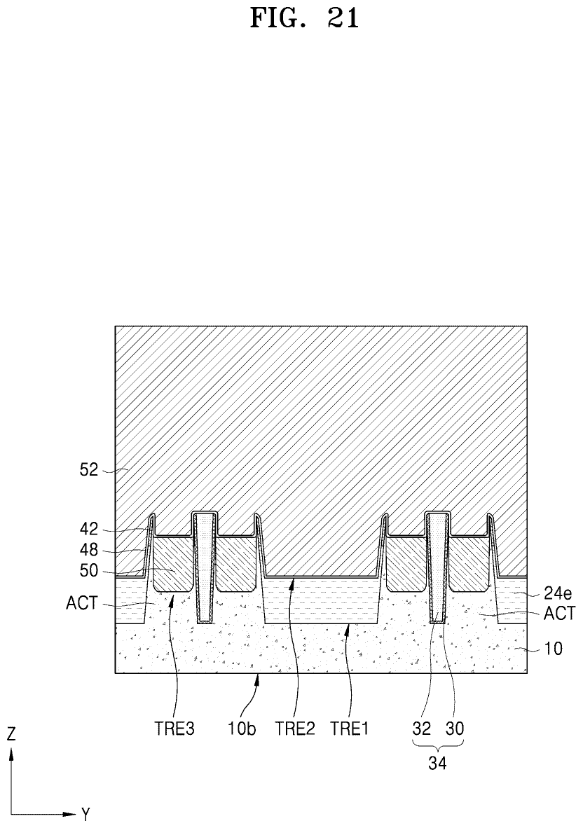

Referring to FIGS. 20 and 21, the placeholders 50 are formed within the third trench TRE3 as illustrated in FIG. 20. The placeholders 50 may be formed on the fin-type active regions ACT. The placeholders 50 may be formed by selectively epitaxially growing a semiconductor material within the third trench TRE3 on the fin-type active regions ACT.

The placeholders 50 may be an epi layer doped with impurities. In some embodiments, the placeholders 50 may be an epitaxially grown Si layer, an epitaxially grown SiC layer, or an epitaxially grown SiGe layer. Next, the second field insulating layer 48 is formed on the placeholders 50, the first dielectric wall structure 34, and the fifth field insulating pattern 24c.

The second field insulating layer 48 may include a nitride layer. Accordingly, the second field insulating layer 48 may be formed on the fifth field insulating pattern 24e, i.e., on the first field insulating layer one sidewall of the fin-type active regions ACT. The second field insulating layer 48 may have a smaller thickness than the fifth field insulating pattern 24c. As illustrated in FIG. 21, an interlayer insulating layer 52 is formed on the second field insulating layer 48. The interlayer insulating layer 52 may include an oxide layer.

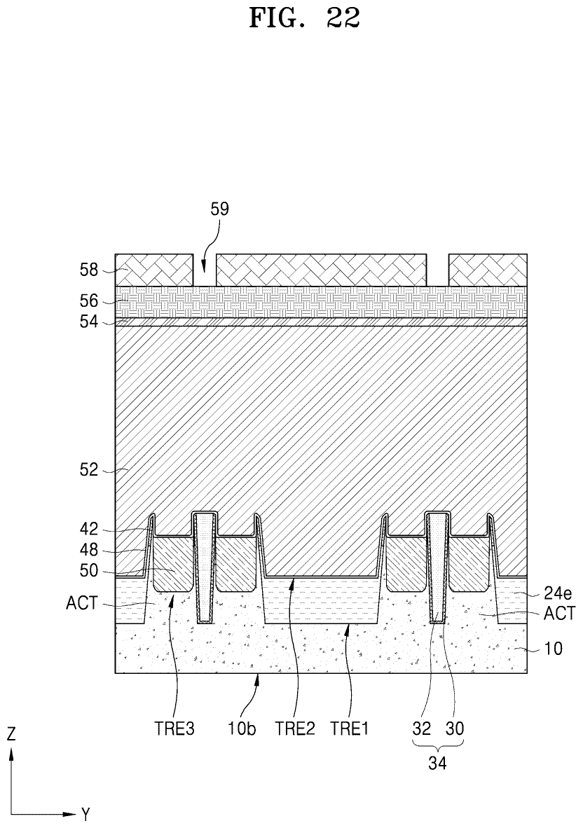

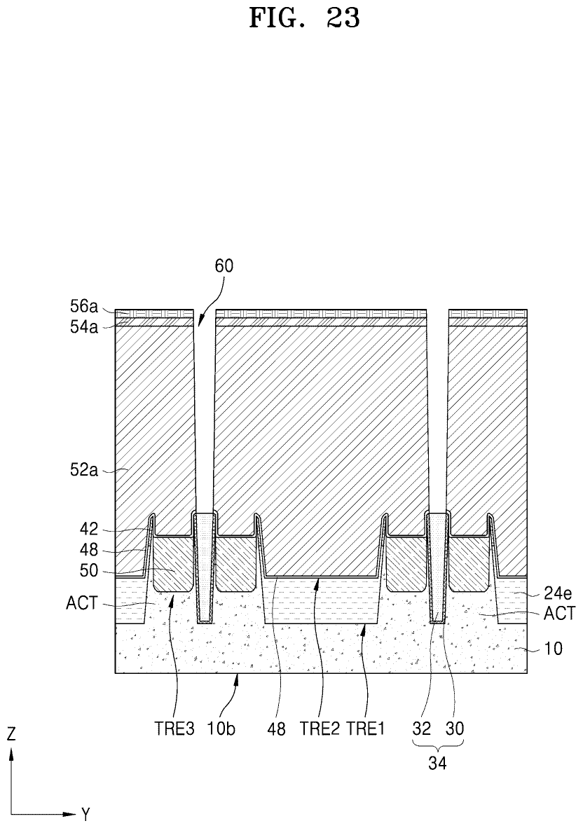

Referring to FIGS. 22 and 23, a second capping insulating layer 54 and a third capping insulating layer 56 are formed on the interlayer insulating layer 52 as illustrated in FIG. 22. The second capping insulating layer 54 and the third capping insulating layer 56 may include an oxide layer and a nitride layer, respectively.

Fourth mask patterns 58 positioned apart from each other are formed on the third capping insulating layer 56. A third opening 59 may be formed between the fourth mask patterns 58. The third opening 59 may be located above the first dielectric wall structure 34.

As illustrated in FIG. 23, the fourth mask patterns (FIG. 58 of FIG. 22) are used as etching masks to etch the third capping insulating layer 56, the second capping insulating layer 54, and the interlayer insulating layer 52 to form a second active hole 60 that exposes a portion above the first dielectric wall structure 34.

When forming the second active hole 60, the fourth mask patterns (58 of FIG. 22) may be removed. When forming the second active hole 60, the third capping insulating layer 56, the second capping insulating layer 54, and the interlayer insulating layer 52 may be a third capping insulating pattern 56a, a second capping insulating pattern 54a, and an interlayer insulating pattern 52a, respectively.

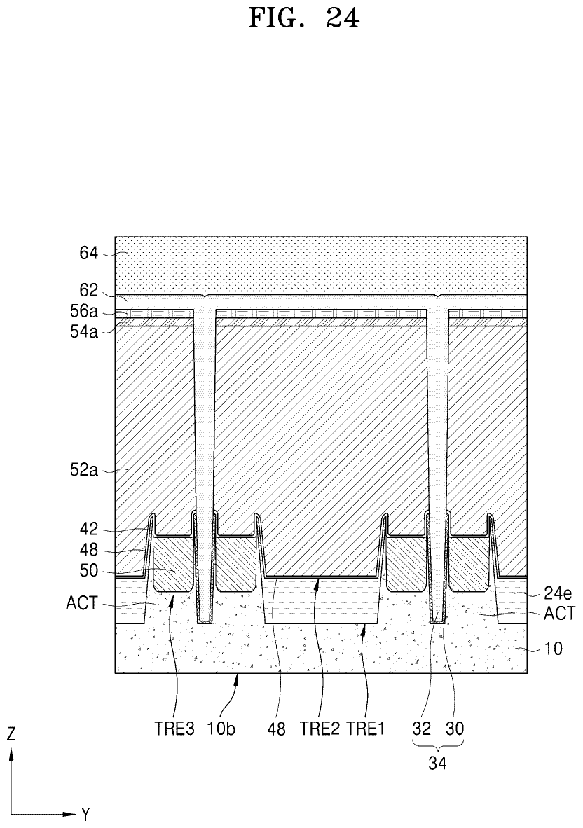

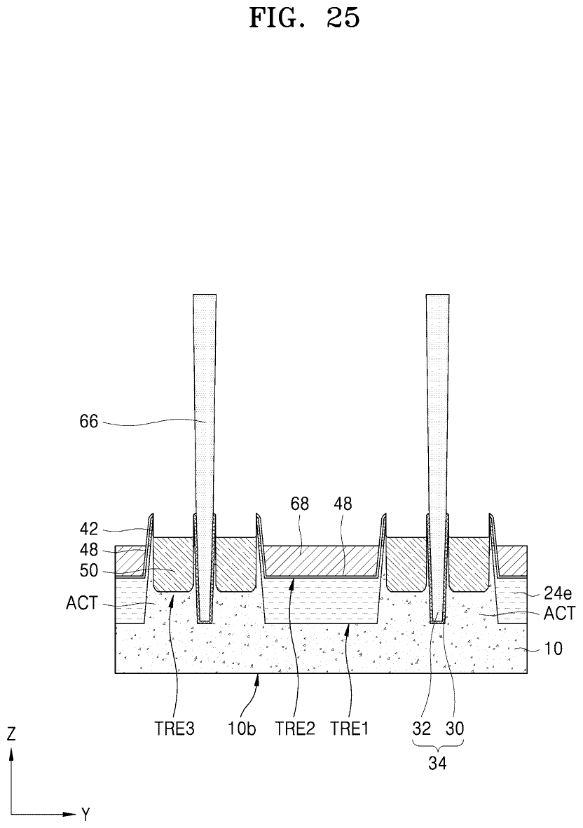

Referring to FIGS. 24 and 25, a second wall insulating material layer 62 is formed to fill a second active hole (60 of FIG. 23) on the third capping insulating pattern 56a as illustrated in FIG. 24. The second wall insulating material layer 62 may include a nitride layer. A fourth capping insulating layer 64 is formed on the second insulating material layer 62. The fourth capping insulating layer 64 may include a nitride layer.

As illustrated in FIG. 25, the second wall insulating material layer (62 in FIG. 24), the third capping insulating pattern (56a in FIG. 24), and the second capping insulating pattern (54a in FIG. 24) on the fourth capping insulating layer (64 in FIG. 24), the third capping insulating pattern (56a in FIG. 24) are planarized by chemical mechanical polishing. The interlayer insulating layer 52 is selectively etched to form the second dielectric wall structure 66 on the first dielectric wall structure 34, and the third field insulating layer 68 is formed on the second field insulating layer 48.

The second dielectric wall structure 66 may be a second wall insulating layer formed within the second active hole (60 of FIG. 23). By forming the second dielectric wall structure 66, the dielectric wall structure (DW of FIG. 2) including the first dielectric wall structure 34 and the second dielectric wall structure 66 may be formed.

On one sidewall (e.g., an outer sidewall) of the fin-type active regions ACT, the second field insulating layer 48 and the third field insulating layer 68 may be formed on the first field insulating layer 24c. Accordingly, the field regions (FD in FIG. 2) including the first field insulating layer 24c, the second field insulating layer 48, and the third field insulating layer 68 may be formed. The first field insulating layer 24c, the second field insulating layer 48, and the third field insulating layer 68 protect or otherwise do not expose the sidewalls of the fin-type active regions ACT, thereby reducing or suppressing the growth of a parasitic conductive layer (or parasitic epilayer) on one sidewall (e.g., an outer sidewall) of each of the fin-type active regions ACT in a subsequent process.

Further, the first to fourth source and drain regions SD1, SD2, SD3, and SD4 are formed on the placeholders 50 as illustrated in FIG. 2. The integrated circuit semiconductor device 100 may be completed by forming the cover layer 70 on the first to fourth source and drain regions SD1, SD2, SD3, and SD4, the spacers 42, and the field regions FD.

Although the inventive concept has been described with reference to the embodiments illustrated in the drawings, these are merely examples, and those skilled in the art will understand that various modifications, substitutions, and equivalent other embodiments are possible. It should be understood that the embodiments described above are examples in all respects and not limiting. The scope of the inventive concept should be determined by the appended claims.

While the inventive concept has been particularly shown and described with reference to embodiments thereof, it will be understood that various changes in form and details may be made therein without departing from the scope of the following claims.

What is claimed is:

1. An integrated circuit semiconductor device, comprising:
a plurality of fin-type active regions protruding from a substrate, extending in a first direction on the substrate, and spaced apart from each other in a second direction intersecting the first direction;
nano sheet stacking structures on the fin-type active regions;
a dielectric wall structure extending in the first direction, wherein the dielectric wall structure is between a pair of the fin-type active regions and is between the nano sheet stacking structures thereon in the second direction;
field regions within trenches in the substrate that separate the fin-type active regions, the field regions comprising a multi-insulating layer; and
a plurality of gate structures extending in the second direction on the nano sheet stacking structures and spaced apart from each other in the first direction.

2. The integrated circuit semiconductor device of claim 1, wherein the multi-insulating layer comprises a triple insulating layer of a first field insulating layer, a second field insulating layer, and a third field insulating layer sequentially provided within the trenches.

3. The integrated circuit semiconductor device of claim 2, wherein the first field insulating layer, the second field insulating layer, and the third field insulating layer comprise a first oxide layer, a first nitride layer, and a second oxide layer, respectively, and wherein a thickness of the second field insulating layer is less than respective thicknesses of the first field insulating layer and the third field insulating layer.

4. The integrated circuit semiconductor device of claim 1, wherein the multi-insulating layer comprises a double insulating layer of a first field insulating layer and a second field insulating layer sequentially provided within the trenches.

5. The integrated circuit semiconductor device of claim 4, wherein the first field insulating layer and the second field insulating layer each comprise a first oxide layer and a first nitride layer, and a thickness of the second field insulating layer is less than a thickness of the first field insulating layer.

6. The integrated circuit semiconductor device of claim 1, wherein the field regions and the dielectric wall structure are provided on outer sidewalls and inner sidewalls, respectively, of the pair of the fin-type active regions.

7. The integrated circuit semiconductor device of claim 6, further comprising:
spacers on the outer sidewalls of the fin-type active regions.

8. The integrated circuit semiconductor device of claim 1, wherein upper surfaces of the field regions are below upper surfaces of the fin-type active regions, relative to the substrate.

9. The integrated circuit semiconductor device of claim 1, wherein upper surfaces of the field regions are coplanar with upper surfaces of the fin-type active regions.

10. An integrated circuit semiconductor device comprising:
a plurality of fin-type active regions protruding from a substrate and spaced apart from each other;
nano sheet stacking structures on the fin-type active regions;
placeholders within the fin-type active regions;
source and drain regions on the placeholders;
a dielectric wall structure separating a pair of the fin-type active regions, the dielectric wall structure extending between pair of the fin-type active regions, between the nano sheet stacking structures thereon, between the placeholders therein, and between the source and drain regions thereon;
field regions within trenches in the substrate that separate the fin-type active regions, the field regions each comprising a multi-insulating layer; and
a plurality of gate structures on the nano sheet stacking structures.

11. The integrated circuit semiconductor device of claim 10, wherein the multi-insulating layer comprises a triple insulating layer of a first field insulating layer, a second field insulating layer, and a third field insulating layer sequentially provided within the trenches,
the first field insulating layer, the second field insulating layer, and the third field insulating layer comprise a first oxide layer, a first nitride layer, and a second oxide layer, respectively, and
a thickness of the second field insulating layer is less than respective thicknesses of the first field insulating layer and the third field insulating layer.

12. The integrated circuit semiconductor device of claim 10, wherein the multi-insulating layer comprises a double insulating layer of a first field insulating layer and a second field insulating layer,
the first field insulating layer and the second field insulating layer comprise a first oxide layer and a first nitride layer, respectively, and
a thickness of the second field insulating layer is less than a thickness of the first field insulating layer.

13. The integrated circuit semiconductor device of claim 10, wherein the field regions and the dielectric wall structure are provided on outer sidewalls and inner sidewalls, respectively, of the pair of the fin-type active regions and the placeholders therein.

14. The integrated circuit semiconductor device of claim 13, further comprising:
spacers on the outer sidewalls of the pair of the fin-type active regions.

15. The integrated circuit semiconductor device of claim 10, wherein upper surfaces of the field regions are below upper surfaces of the fin-type active regions and upper surfaces of the placeholders, relative to the substrate.

16. The integrated circuit semiconductor device of claim 10, wherein upper surfaces of the field regions are coplanar with upper surfaces of the fin-type active regions and upper surfaces of the placeholders.

17. An integrated circuit semiconductor device comprising:
a plurality of fin-type active regions protruding from a substrate, extending in a first direction with respect to the substrate, and spaced apart from each other in a second direction that intersects the first direction;
nano sheet stacking structures on the fin-type active regions;
placeholders within the fin-type active regions;
source and drain regions on the placeholders;
a dielectric wall structure extending in the first direction and separating, in the second direction, a pair of the fin-type active regions, the nano sheet stacking structures thereon, the placeholders therein, and the source and drain regions thereon;
field regions within trenches in the substrate that separate the fin-type active regions, the field regions each comprising a multi-insulating layer; and
a plurality of gate structures extending in the second direction on the nano sheet stacking structures and spaced apart from each other in the first direction.

18. The integrated circuit semiconductor device of claim 17, wherein the multi-insulating layer comprises a triple insulating layer of a first field insulating layer, a second field insulating layer, and a third field insulating layer sequentially provided within the trenches,
the first field insulating layer, the second field insulating layer, and the third field insulating layer comprise a first oxide layer, a first nitride layer, and a second oxide layer, respectively.

19. The integrated circuit semiconductor device of claim 17, wherein the field regions and the dielectric wall structure are provided on outer sidewalls and inner sidewalls, respectively, of the pair of the fin-type active regions and the placeholders therein.

20. The integrated circuit semiconductor device of claim 17, wherein upper surfaces of the field regions are positioned below or are coplanar with upper surfaces of the fin-type active regions and upper surfaces of the placeholders, relative to the substrate.
